(19) United States
(12) Patent Application Publication
(10) Pub. No.: US 2022/0181326 A1
(43) Pub. Date: Jun. 9, 2022

(54) SEMICONDUCTOR MEMORY DEVICE

(71) Applicant: SAMSUNG ELECTRONICS CO., LTD., Suwon-si (KR)

(72) Inventors: Hokyun An, Seoul (KR); Sungmi Yoon, Seoul (KR)

(21) Appl. No.: 17/377,932

(22) Filed: Jul. 16, 2021

(30) Foreign Application Priority Data
Dec. 9, 2020 (KR) 10-2020-0171372

(51) Int. Cl. H01L 27/108

(52) U.S. Cl. CPC H01L 27/10826; H01L 27/10879; H01L 27/10855; H01L 27/10814

(57) ABSTRACT

Disclosed is a semiconductor memory device comprising a substrate with active patterns including first and second source/drain regions, a gate electrode extending across the active patterns in a first direction between the first and second source/drain regions, a line structure extending across the active patterns in a second direction that is transverse to the first direction and including a bit line electrically connected to the first source/drain region, a device isolation layer within a first trench which defines the active patterns, and contacts coupled to the second source/drain regions. The active pattern includes a first portion extending in a third direction parallel to a top surface of the substrate, and second and third portions connected to opposite ends of the first portion and vertically overlapping respective contacts. The second and third portions extend toward the respective contacts.

### CROSS-REFERENCE TO RELATED APPLICATION

This U.S. nonprovisional application claims priority under 35 U.S.C. § 119 to Korean Patent Application No. 10-2020-0171372 filed on Dec. 9, 2020 in the Korean Intellectual Property Office, the entire contents of which are hereby incorporated by reference.

### FIELD

The present inventive concepts relate to a semiconductor memory device, and more particularly to, a semiconductor memory device with improved electrical characteristics and a method of fabricating the same.

### BACKGROUND

Semiconductor devices have an important role in the electronics industry because of their small size, multi-functionality, and/or low fabrication cost. Data storage devices among the semiconductor devices can store logic data. The data storage devices are increasingly integrated with the development of the electronics industry. As a result, line widths of components constituting data storage devices continue to decrease.

Additionally, high reliability has been demanded with the high integration of data storage devices. However, high integration may reduce reliability of data storage devices. Therefore, various studies have been conducted to improve the reliability of data storage devices.

### SUMMARY

Some embodiments of the present inventive concepts provide a semiconductor memory device with improved electrical characteristics.

Some embodiments of the present inventive concepts provide a method of fabricating a semiconductor memory device with improved electrical characteristics.

According to some embodiments of the present inventive concepts, a semiconductor memory device may comprise: a substrate having a plurality of active patterns, each of the plurality of active patterns including a first source/drain region and second source/drain regions; a gate electrode extending across the plurality of active patterns in a first direction between the first and second source/drain regions; a line structure extending across the plurality of active patterns in a second direction which is transverse to the first direction, the line structure including a bit line electrically connected to the first source/drain region; a device isolation layer within a first trench which defines the plurality of active patterns; and a plurality of contacts coupled to the second source/drain regions. When viewed in plan, each of the plurality of active patterns may include: a first portion extending in a third direction parallel to a top surface of the substrate; and a second portion and a third portion respectively connected to opposite ends of the first portion, wherein the second and third portions vertically overlap respective ones of the plurality of contacts. The second portion and the third portion may extend toward the respective ones of the plurality of contacts.

According to some embodiments of the present inventive concepts, a semiconductor memory device may comprise: a substrate having a plurality of active patterns, each of the plurality of active patterns including a first source/drain region and a second source/drain region; a gate electrode extending across the plurality of active patterns in a first direction between the first and second source/drain regions; a line structure extending across the plurality of active patterns in a second direction which is transverse to the first direction, the line structure including a bit line electrically connected to the first source/drain region; a device isolation layer within a first trench which defines the plurality of active patterns; and a contact coupled to the second source/drain region. A width of each of the plurality of active patterns may increase with increasing distance from a bottom surface of the substrate.

According to some embodiments of the present inventive concepts, a semiconductor memory device may comprise: a substrate having a plurality of active patterns, each of the plurality of active patterns including a first source/drain region and a second source/drain region; a gate electrode extending across the plurality of active patterns in a first direction between the first and second source/drain regions; a dielectric layer on the substrate; a line structure extending across the plurality of active patterns in a second direction on the dielectric layer, wherein the second direction is transverse to the first direction, the line structure including a conductive pattern coupled to the first source/drain region, a bit line on the conductive pattern, and a barrier pattern between the bit line and the conductive pattern; a pair of spacers on opposite sidewalls of the line structure; a device isolation layer within a first trench which defines the plurality of active patterns; a plurality of contacts coupled to the second source/drain regions, the plurality of contacts are in contact with corresponding spacers that separate the plurality of contacts from the line structure; a landing pad on each of the plurality of contacts; and a data storage element on each landing pad. The data storage element may include: a first electrode on a respective landing pad; a second electrode on the first electrode; and a dielectric layer between the first electrode and the second electrode. When viewed in plan, each of the plurality of active patterns may include: a first portion extending in a third direction parallel to a top surface of the substrate; and a second portion and a third portion respectively connected to opposite ends of the first portion, wherein the second and third portions vertically overlap respective ones of the plurality of contacts. The second portion and the third portion may extend toward the respective ones of the plurality of contacts.

### BRIEF DESCRIPTION OF THE DRAWINGS

FIG. 1A is a plan view illustrating a semiconductor device according to some embodiments of the present inventive concepts.

FIG. 1B is a plan view of active patterns and contacts depicted in FIG. 1A, illustrating a semiconductor memory device according to some embodiments of the present inventive concepts.

FIGS. 2A, 2C, 2D, and 2E are cross-sectional views respectively taken along lines A-A′, B-B′, C-C′, and D-D′ of FIG. 1A or 1B.

FIG. 2B is an enlarged view illustrating section A of FIG. 2A.

FIGS. 3, 5, 7, 9, 11, 13, 15, and 17 are plan views illustrating a method of fabricating a semiconductor memory device according to some embodiments of the present inventive concepts.

FIGS. 4A, 6A, 8A, 10A, 12A, 14A, 16A, and 18A are cross-sectional views taken along line A-A′ of FIGS. 3, 5, 7, 9, 11, 13, 15, and 17, respectively.

FIGS. 4B, 6B, 8B, 10B, 12B, 14B, 16B, and 18B are cross-sectional views taken along line B-B′ of FIGS. 3, 5, 7, 9, 11, 13, 15, and 17, respectively.

FIGS. 4C, 6C, 8C, 10C, 12C, 14C, 16C, and 18C are cross-sectional views taken along line C-C′ of FIGS. 3, 5, 7, 9, 11, 13, 15, and 17, respectively.

FIGS. 4D, 6D, 8D, 10D, 12D, 14D, 16D, and 18D are cross-sectional views taken along line D-D′ of FIGS. 3, 5, 7, 9, 11, 13, 15, and 17, respectively.

### DETAILED DESCRIPTION OF EMBODIMENTS

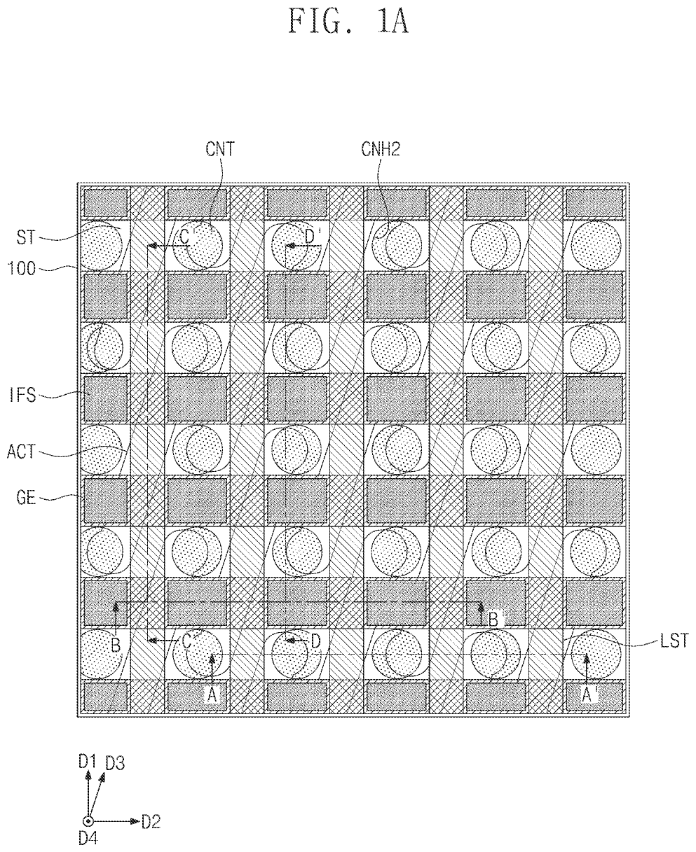

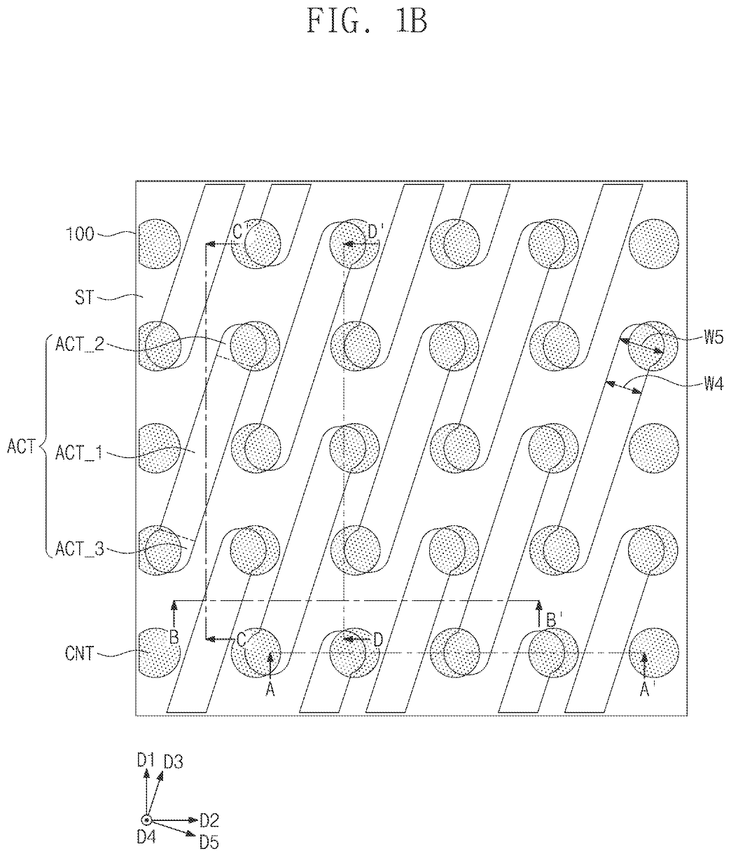

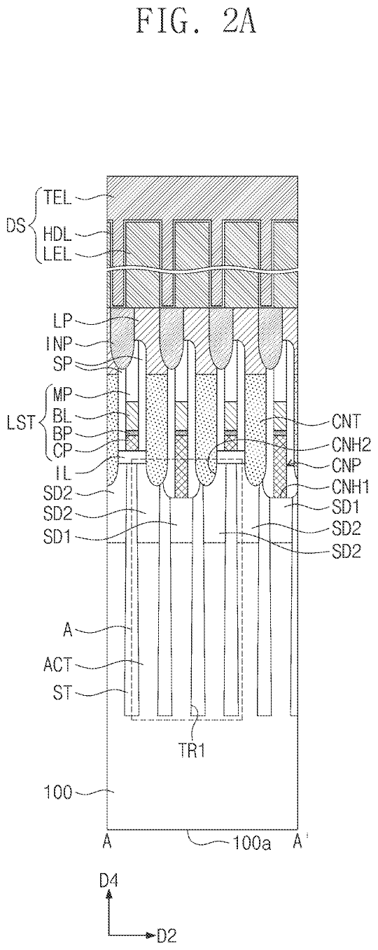

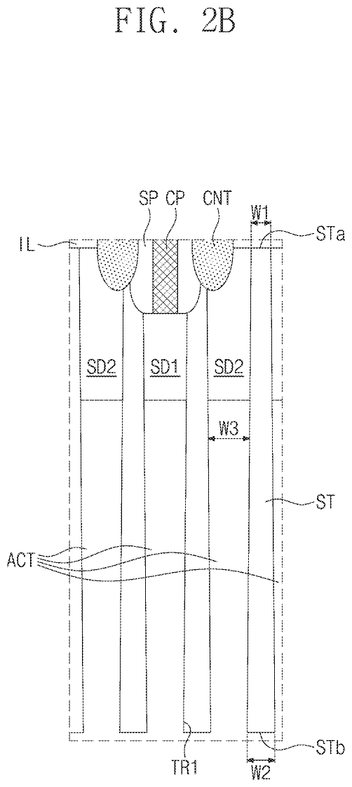

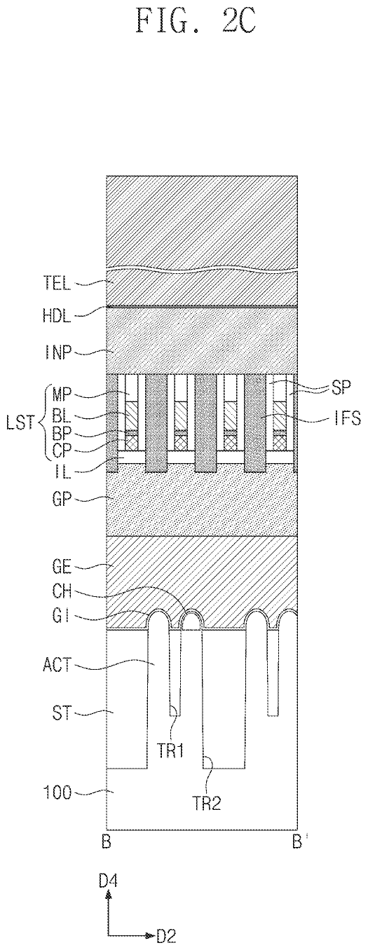

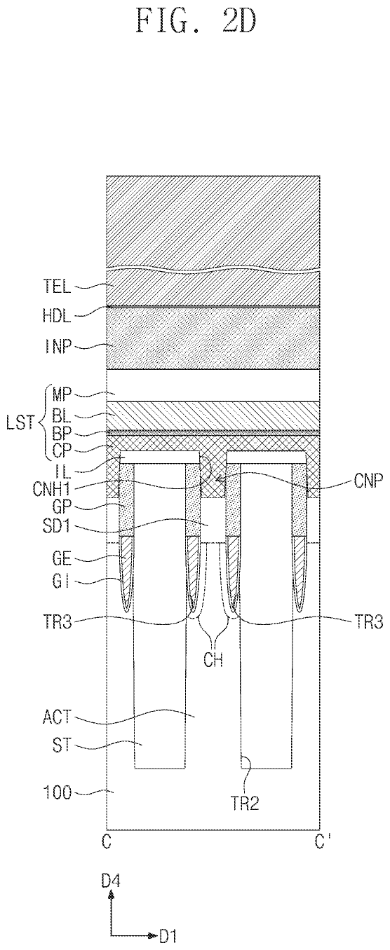

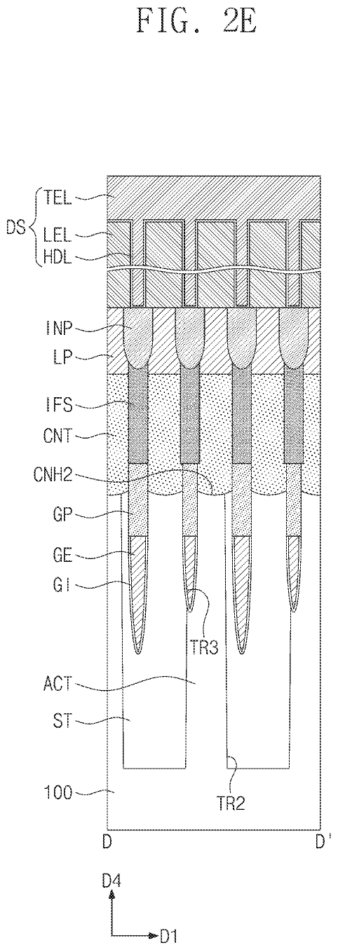

FIG. 1A is a plan view illustrating a semiconductor memory device according to some embodiments of the present inventive concepts. FIGS. 2A, 2C, 2D, and 2E are cross-sectional views respectively taken along lines A-A′, B-B′, C-C′, and D-D′ of FIG. 1A or 1B.

Referring to FIGS. 1A, 2A, 2C, 2D, and 2E, a substrate 100 may be provided thereon with a device isolation layer ST that defines active patterns ACT. For example, the substrate 100 may be a semiconductor substrate including silicon, germanium, or silicon-germanium. The device isolation layer ST may include a silicon oxide layer.

The active patterns ACT may be formed when an upper portion of the substrate 100 is patterned. Each of the active patterns ACT may extend in a third direction D3 parallel to a top surface of the substrate 100, as illustrated in FIG. 1A. For example, each of the active patterns ACT may have a major axis in the third direction D3. The active patterns ACT may be two-dimensionally arranged along a first direction D1 and a second direction D2. The active patterns ACT may be spaced apart from each other in the third direction D3.

With reference to FIGS. 1B and 2B, the following will describe in detail planar and cross-sectional structures of each of the active patterns ACT.

First and second trenches TR1 and TR2 (FIG. 2C) may be defined between the active patterns ACT. The device isolation layer ST may fill the first and second trenches TR1 and TR2 between the active patterns ACT. The first trench TR1 may be defined between a pair of active patterns ACT that are adjacent to each other in the second direction D2. The second trench TR2 may be defined between a pair of active patterns ACT that are adjacent to each other in the third direction D3.

A distance between a pair of active patterns ACT adjacent to each other in the second direction D2 may be less than a distance between a pair of active patterns ACT adjacent to each other in the third direction D3. The second trench TR2 may be deeper than the first trench TR1. For example, the second trench TR2 may have a floor lower than that of the first trench TR1 (see FIG. 2C).

Each of the active patterns ACT may have, on its upper portion, a first source/drain region SD1 (FIGS. 2A, 2B) and a pair of second source/drain regions SD2 (FIGS. 2A, 2B). The first source/drain region SD1 may be placed between the pair of second source/drain regions SD2. In such a configuration, when viewed in plan, the second source/drain region SD2, the first source/drain region SD1, and the second source/drain region SD2 may be sequentially arranged along the third direction D3.

A pair of third trenches TR3 may be defined on each of the active patterns ACT (see FIG. 2D). Each of the third trenches TR3 may be defined between the first source/drain region SD1 and the second source/drain region SD2. The third trench TR3 may penetrate the upper portion of the active pattern ACT, and may extend downwardly from a top surface of the active pattern ACT toward a bottom surface (see 100a of FIG. 2A) of the substrate 100. The third trench TR3 may have a floor higher than those of the first and second trenches TR1 and TR2.

Each of the active patterns ACT may further include a pair of channel regions CH on the upper portion thereof. When viewed in plan, the channel region CH may be interposed between the first source/drain region SD1 and the second source/drain region SD2. The channel region CH may be disposed below the third trench TR3 (see FIG. 2D). The channel region CH may thus be positioned lower than the first and second source/drain regions SD1 and SD2.

Gate electrodes GE may be provided to run (i.e., extend) across the active patterns ACT and the device isolation layer ST. The gate electrodes GE may be provided in corresponding third trenches TR3, as illustrated in FIG. 2D. The gate electrodes GE may extend in parallel to each other in the second direction D2. A pair of gate electrodes GE may be provided on a pair of channel regions CH of the active pattern ACT. For example, when viewed in plan, the gate electrode GE may be interposed between the first source/drain region SD1 and the second source/drain region SD2. The gate electrode GE may have a top surface lower than that of the active pattern ACT (e.g., that of the first source/drain region SD1 or that of the second source/drain region SD2).

Referring back to FIG. 2C, an upper portion of the gate electrode GE may be adjacent to the first source/drain region SD1 of the active pattern ACT. A lower portion of the gate electrode GE may be adjacent to the channel region CH.

Referring to FIGS. 1A, 2A, and 2C to 2E, a gate dielectric layer GI may be interposed between the gate electrode GE and the active pattern ACT. A gate capping layer GP may be provided on the gate electrode GE. The gate capping layer GP may cover the top surface of the gate electrode GE. The gate capping layer GP may have a top surface coplanar with that of the active pattern ACT.

The gate electrode GE may include one or more of conductive metal nitride (e.g., titanium nitride or tantalum nitride) and metal (e.g., titanium, tantalum, tungsten, copper, or aluminum). The gate dielectric layer GI may include one or more of a silicon oxide layer, a silicon nitride layer, a silicon oxynitride layer, and a high-k dielectric material. For example, the high-k dielectric material may include hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or a combination thereof. The gate capping layer GP may include one or more of a silicon oxide layer, a silicon nitride layer, and a silicon oxynitride layer.

A dielectric layer IL may be provided on the substrate 100. The dielectric layer IL may include first contact holes CNH1 that expose the first source/drain regions SD1 of the active patterns ACT, as illustrated in FIG. 2A. For example, the dielectric layer IL may include a first dielectric layer and a second dielectric layer that are sequentially stacked. The second dielectric layer may have a dielectric constant greater than that of the first dielectric layer. For example, the first dielectric layer may include a silicon oxide layer, and the second dielectric layer may include a silicon oxynitride layer.

The dielectric layer IL may be provided thereon with line structures LST that extend in parallel to each other in the first direction D1. The line structures LST may be arranged along the second direction D2. When viewed in plan, the line structures LST may orthogonally intersect the gate electrodes GE (see FIG. 1A). A pair of spacers SP may be provided on opposite sidewalls of each of the line structures LST. The spacers SP may include one or more of a silicon oxide layer, a silicon nitride layer, and a silicon oxynitride layer.

Each of the line structures LST may include a conductive pattern CP, a barrier pattern BP, a bit line BL, and a mask pattern MP that are sequentially stacked, as illustrated in FIG. 2A. The conductive pattern CP may include a contact part CNP that fills the first contact hole CNH1 and contacts the first source/drain region SD1. For example, the contact part CNP may penetrate the dielectric layer IL and extend toward the bottom surface of the substrate 100. The contact part CNP may have a bottom surface in direct contact with the first source/drain region SD1.

The barrier pattern BP may suppress the conductive pattern CP from receiving a metallic material diffused from the bit line BL. The bit line BL may be electrically connected to the first source/drain region SD1 through the barrier pattern BP and the conductive pattern CP.

The conductive pattern CP may include a doped semiconductor material (e.g., doped silicon or doped germanium). The barrier pattern BP may include conductive metal nitride (e.g., titanium nitride or tantalum nitride). The bit line BL may include a metallic material (e.g., titanium, tantalum, tungsten, copper, or aluminum).

A plurality of dielectric fences IFS may be provided on the gate capping layer GP, as illustrated in FIG. 2E. Each of the dielectric fences IFS may penetrate the dielectric layer IL and extend toward an upper portion of the gate capping layer GP.

Referring back to FIG. 1A, the dielectric fences IFS may be two-dimensionally arranged along the first and second directions D1 and D2. For example, the dielectric fences IFS may be arranged along the second direction D2 on the gate capping layer GP that extends in the second direction D2. The dielectric fences IFS and the line structures LST may be alternately arranged along the second direction D2.

Contacts CNT may be provided to penetrate the dielectric layer IL and to contact corresponding second source/drain regions SD2, as illustrated in FIG. 2A. Each of the contacts CNT may fill a second contact hole CNH2 that is formed by partially etching an upper portion of the second source/drain region SD2. Referring back to FIG. 2A, the contact CNT may be in direct contact with the second source/drain region SD2 exposed to the second contact hole CNH2. In addition, the contact CNT may be in contact with a sidewall of the spacer SP and a top surface of the device isolation layer ST. The spacer SP may separate the contact CNT from the line structure LST adjacent to the contact CNT. Each of the contacts CNT may include a doped semiconductor material (e.g., doped silicon or doped germanium).

Referring again to FIG. 1A, the contacts CNT may be two-dimensionally arranged along the first and second directions D1 and D2. For example, the contacts CNT and the line structures LST may be alternately arranged along the second direction D2. The contacts CNT and the dielectric fences IFS may be alternately arranged along the first direction D1.

The contacts CNT may be provided thereon with landing pads LP coupled to corresponding contacts CNT, as illustrated in FIG. 2A. The landing pads LP may be electrically connected through the contacts CNT to corresponding second source/drain regions SD2. The landing pad LP may be misaligned with the contact CNT. For example, the landing pad LP may be horizontally offset from a center of the contact CNT (see FIG. 2A). The landing pads LP may include a metallic material (e.g., titanium, tantalum, tungsten, copper, or aluminum).

A dielectric pattern INP may be provided on the mask patterns MP. The dielectric pattern INP may define planar shapes of the landing pads LP. The dielectric pattern INP may separate neighboring landing pads LP from each other.

A data storage element DS may be provided on the landing pads LP, as illustrated in FIG. 2A. For example, the data storage element DS may include first electrodes LEL provided on corresponding landing pads LP. The first electrodes LEL may be connected to the corresponding landing pads LP. The data storage element DS may further include a second electrode TEL on the first electrodes LEL and a dielectric layer HDL between the first electrodes LEL and the second electrode TEL. The first electrode LEL, the dielectric layer HDL, and the second electrode TEL may constitute a capacitor in which data is stored.

Each of the first electrodes LEL may have a solid pillar shape, but the present inventive concepts are not limited thereto. In some embodiments, each of the first electrodes LEL may have a cylindrical shape whose bottom is closed. A plurality of first electrodes LEL may be zigzag arranged along the first direction D1 or the second direction D2 to have a honeycomb-shaped arrangement. Alternatively, a plurality of first electrodes LEL may be disposed in a matrix shape along the first and second directions D1 and D2.

Each of the first electrodes LEL may be formed of, for example, impurity-doped silicon, metal such as tungsten, or conductive metal compound such as titanium nitride. The dielectric layer HDL may include a high-k dielectric material, such as hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or a combination thereof. The second electrode TEL may include doped silicon, Ru, RuO, Pt, PtO, Ir, IrO, SRO(SrRuO), BSRO((Ba,Sr)RuO), CRO(CaRuO), BaRuO, La(Sr,Co)O, Ti, TiN, W, WN, Ta, TaN, TiAlN, TiSiN, TaAlN, TaSiN, or any combination thereof.

FIG. 1B is a plan view of active patterns and contacts depicted in FIG. 1A, illustrating a semiconductor memory device according to some embodiments of the present inventive concepts. With reference to FIG. 1B, the following will describe in detail a planar structure of the active pattern ACT according to the present inventive concepts. For convenience of description, the following will focus on a single active pattern ACT.

Referring to FIG. 1B, when viewed in plan, the active pattern ACT may include a first portion ACT_1, a second portion ACT_2, and a third portion ACT_3. The active pattern ACT may have the first portion ACT_1 at a portion that extends parallel to the third direction D3. The first portion ACT_1 may have a major axis in the third direction D3. The first portion ACT_1 may have a width W4 that is regular or irregular in a fifth direction D5. The fifth direction D5 may be parallel to the top surface of the substrate 100 and orthogonal to the third direction D3.

The second portion ACT_2 and the third portion ACT_3 may be connected to opposite ends of the first portion ACT_1. For example, the second portion ACT_2 and the third portion ACT_3 may extend or expand from the first portion ACT_1 toward neighboring contacts CNT. Therefore, a portion of the second portion ACT_2 and a portion of the third portion ACT_3 may vertically overlap neighboring contacts CNT. For example, the second portion ACT_2 may protrude in the second direction D2 toward one of most adjacent contacts CNT, and the third portion ACT_3 may protrude in a direction, which is opposite to the second direction D2, toward another of most adjacent contacts CNT. In such cases, the protruding direction of the second portion ACT_2 may be opposite to the protruding direction of the third portion ACT_3. When viewed in plan, the second portion ACT_2 and the third portion ACT_3 may be symmetrical to each other about the first portion ACT_1.

The first portion ACT_1 may have a width W4 in the fifth direction D5 less than a width W5 in the fifth direction D5 of the second portion ACT_2 and a width in the fifth direction D5 of the third portion ACT_3. The width W5 in the fifth direction D5 of the second portion ACT_2 may be the same as the width in the fifth direction D5 of the third portion ACT_3. For example, a value of about 1.05 to about 1.2 may be given as a ratio (W5/W4) of the width W5 in the fifth direction D5 of the second portion ACT_2 to the width W4 in the fifth direction D5 of the first portion ACT_1.

FIG. 2B is an enlarged view illustrating section A of FIG. 2A. With reference to FIG. 2B, the following will describe in detail a cross-sectional structure of the active pattern ACT according to the present inventive concepts.

Referring to FIG. 2B together with FIG. 2A, the device isolation layer ST may be provided between the active patterns ACT. For example, the device isolation layer ST may be provided on the substrate 100 and may fill the first trench TR1 that defines the active patterns ACT.

When viewed in cross-section, each of the active patterns ACT may be configured such that the second and third portions ACT_2 and ACT_3 may each have an upper width greater than a lower width. For example, the second and third portions ACT_2 and ACT_3 of each of the active patterns ACT may have their widths W3 in the second direction D2 that increase in a fourth direction D4 with increasing distance from the bottom surface 100a of the substrate 100. A value of about 60 nm to about 100 nm may be given as a maximum of the width W3 in the second direction D2 of each of the second and third portions ACT_2 and ACT_3 of the active pattern ACT. For example, the width W3 in the second direction D2 of the second portion ACT_2 may increase with decreasing distance from the contact CNT most adjacent to the second portion ACT_2, and may decrease with decreasing distance from the bottom surface 100a of the substrate 100. Therefore, an interval in the second direction D2 between neighboring active patterns ACT may decrease with decreasing distance from the top surface of the substrate 100.

Because the second and third portions ACT_2 and ACT_3 of each of the active patterns ACT have their upper widths greater than their lower widths, the device isolation layer ST disposed adjacent to the second and third portions ACT_2 and ACT_3 may have a width in the second direction D2 that decreases with increasing distance from the bottom surface 100a of the substrate 100. For example, the device isolation layer ST may have at its uppermost surface STa a width W1 of about 50 nm to about 100 nm in the second direction D2, and may have at its lowermost surface STb a width W2 of about 52 nm to about 120 nm in the second direction D2. A value of about 1.05 to about 1.2 may be given as a ratio (W2/W1) of the width W2 in the second direction D2 at the lowermost surface STb to the width W1 in the second direction D2 at the uppermost surface STa of the device isolation layer ST. The uppermost surface STa may be a minimum width of the device isolation layer ST, but the present inventive concepts are not limited thereto.

An increase in aspect ratio of the active patterns ACT for high integration may reduce a contact area between the active pattern ACT and the contact CNT, and as a result, contact failure may frequently arise. According to some embodiments of the present inventive concepts, each of the active patterns ACT may include the second portion ACT_2 and the third portion ACT_3 each of which is in physical contact with the contact CNT, and second and third portions ACT_2 and ACT_3 may each have a width that increases with decreasing distance from the contact CNT, which may increase a contact area between the active pattern ACT and the contact CNT. Therefore, the active pattern ACT and the contact CNT may have therebetween improved contact properties, and as a result, a semiconductor memory device may be provided which has increased electrical operating characteristics.

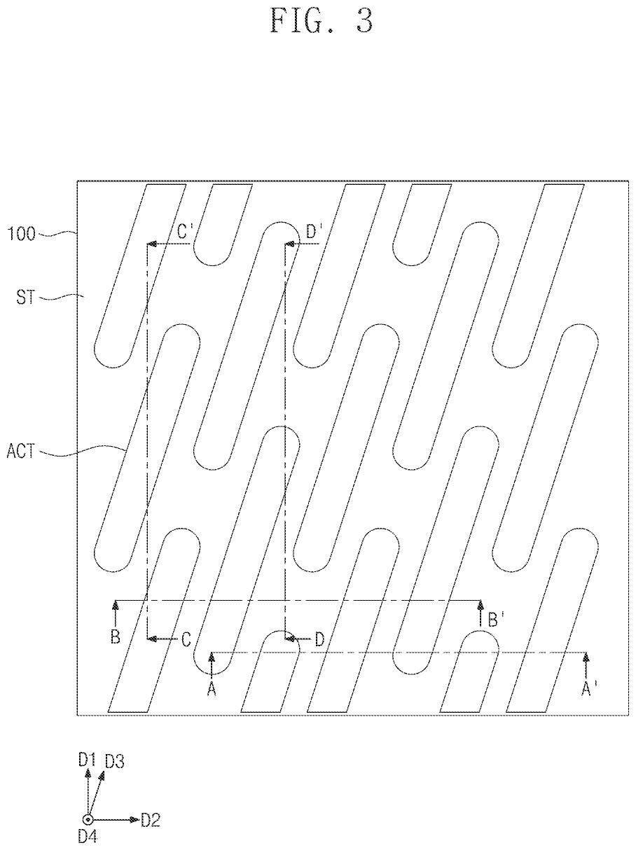

FIGS. 3, 5, 7, 9, 11, 13, 15, and 17 are plan views illustrating a method of fabricating a semiconductor memory device according to some embodiments of the present inventive concepts.

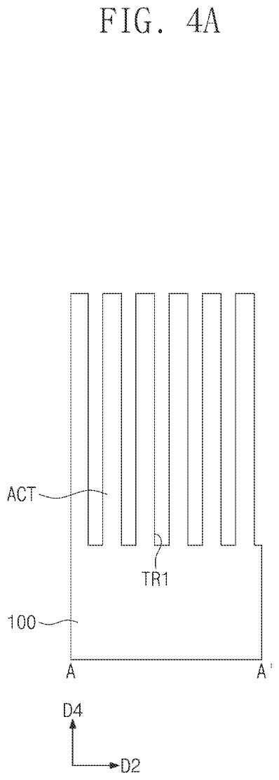

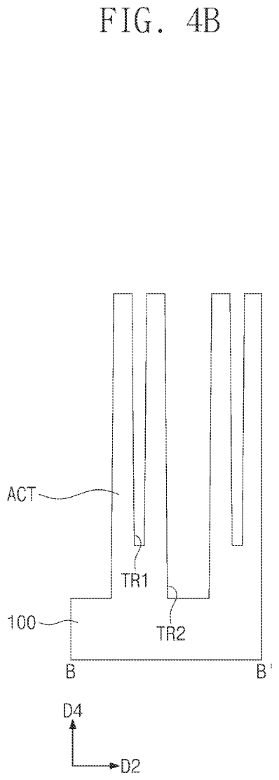

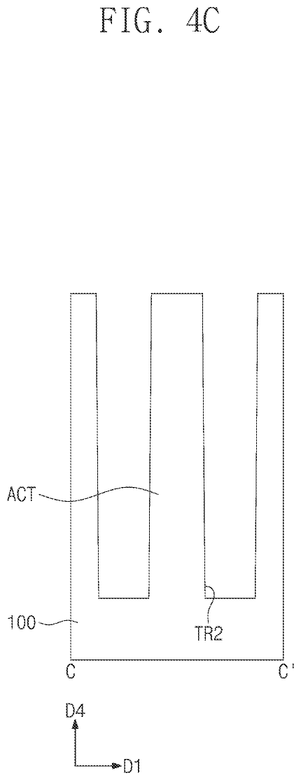

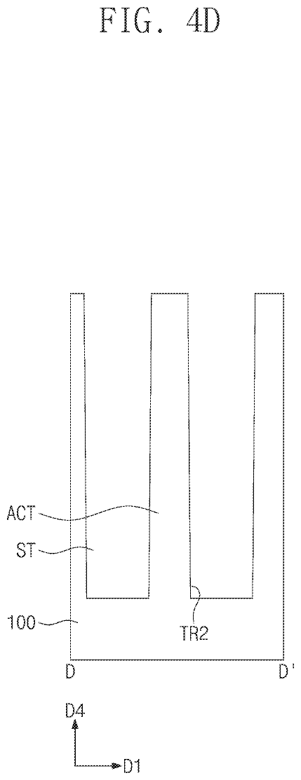

FIGS. 4A, 6A, 8A, 10A, 12A, 14A, 16A, and 18A are cross-sectional views taken along line A-A′ of FIGS. 3, 5, 7, 9, 11, 13, 15, and 17, respectively. FIGS. 4B, 6B, 8B, 10B, 12B, 14B, 16B, and 18B are cross-sectional views taken along line B-B′ of FIGS. 3, 5, 7, 9, 11, 13, 15, and 17, respectively. FIGS. 4C, 6C, 8C, 10C, 12C, 14C, 16C, and 18C are cross-sectional views taken along line C-C′ of FIGS. 3, 5, 7, 9, 11, 13, 15, and 17, respectively. FIGS. 4D, 6D, 8D, 10D, 12D, 14D, 16D, and 18D are cross-sectional views taken along line D-D′ of FIGS. 3, 5, 7, 9, 11, 13, 15, and 17, respectively.

Referring to FIGS. 3 and 4A to 4D, an upper portion of a substrate 100 may be patterned to form active patterns ACT. Each of the active patterns ACT may extend in a third direction D3 parallel to a top surface of the substrate 100. The active patterns ACT may be two-dimensionally arranged along a first direction D1 and a second direction D2. The active patterns ACT may be spaced apart from each other in the third direction D3.

First and second trenches TR1 and TR2 may be defined between the active patterns ACT. The first trench TR1 may be defined between a pair of active patterns ACT that are adjacent to each other in the second direction D2. The second trench TR2 may be defined between a pair of active patterns ACT that are adjacent to each other in the third direction D3.

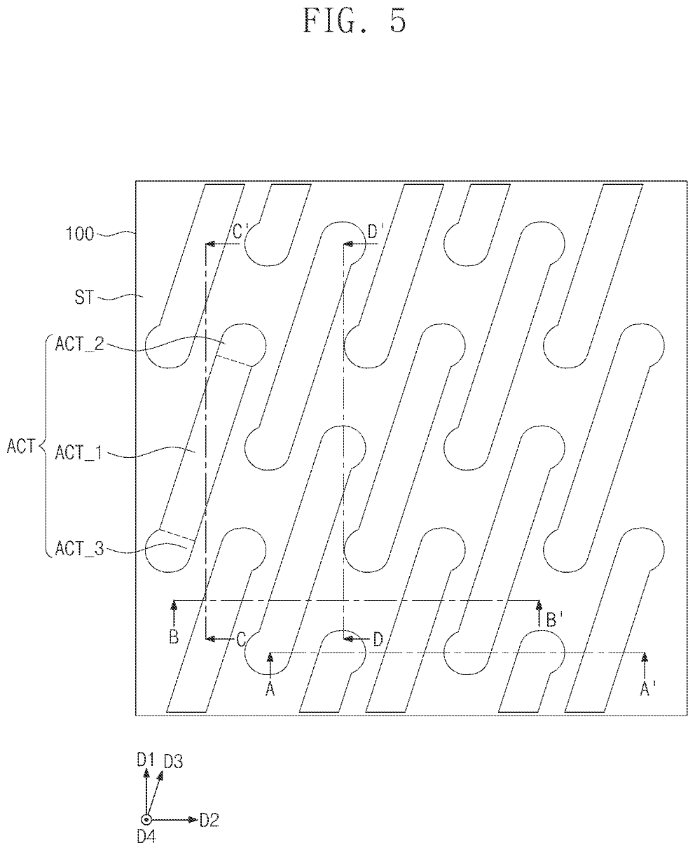

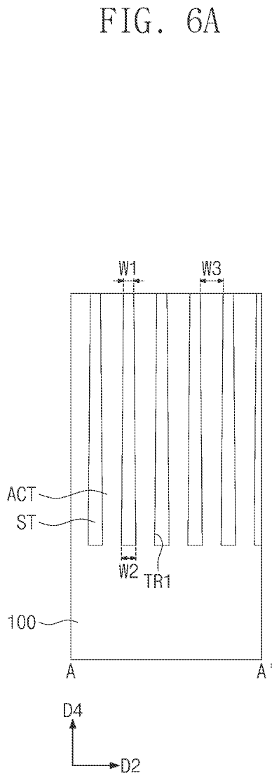

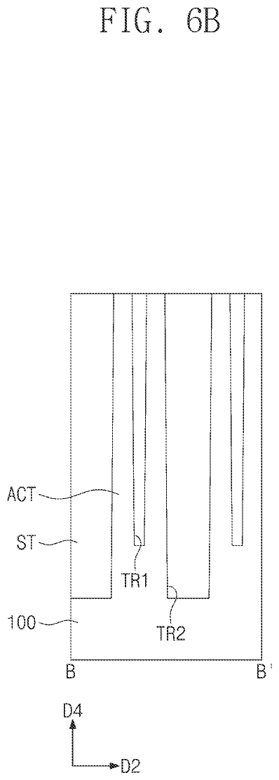

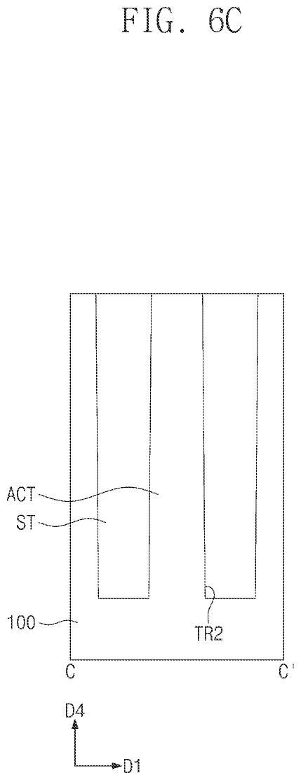

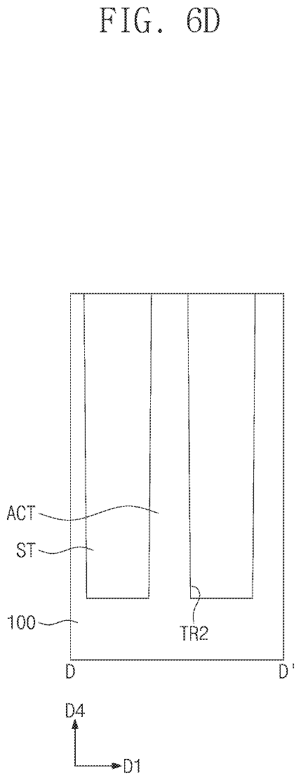

Referring to FIGS. 5 and 6A to 6D, the active patterns ACT may undergo a deposition process to form a second portion ACT_2 and a third portion ACT_3 on each of the active patterns ACT. According to some embodiments, the deposition process may include selectively depositing a silicon-containing source material (e.g., SiH) on the active patterns ACT. For example, the deposition process may be performed such that the active patterns ACT may be provided with a silicon-containing source material in a plasma state together with a carrier gas. In this step, an angle of the substrate 100 or an irradiation angle of the source material may be adjusted to deposit silicon only on desired positions on the active patterns ACT. The deposition process may cause the second and third portions ACT_2 and ACT_3 of each of the active patterns ACT to have widths at upper portions thereof greater than widths at lower portions thereof. Therefore, as shown in FIG. 5, the active patterns ACT may be formed to each have expanded shapes at opposite ends. The silicon deposited by the deposition process may be amorphous silicon. After the deposition process, a device isolation layer ST may be formed to fill the first and second trenches TR1 and TR2. The device isolation layer ST may be formed to completely fill the first and second trenches TR1 and TR2 and to cover the active patterns ACT. A planarization process may be performed on the device isolation layer ST until top surfaces of the active patterns ACT are exposed. Although not shown, according to some embodiments, the deposition process may deposit a silicon layer on any desired location such as not only the opposite ends, but a central portion of each of the active patterns ACT.

Before the deposition process is performed, a cleaning process may be additionally performed on the active patterns ACT. The cleaning process may include, for example, a dry etching process or a wet etching process. The cleaning process may remove impurities and silicon oxide that are irregularly present on surfaces of the active patterns ACT. For example, the dry etching process may use one or more of NF3 and NH3 gases, and the wet etching process may use HF.

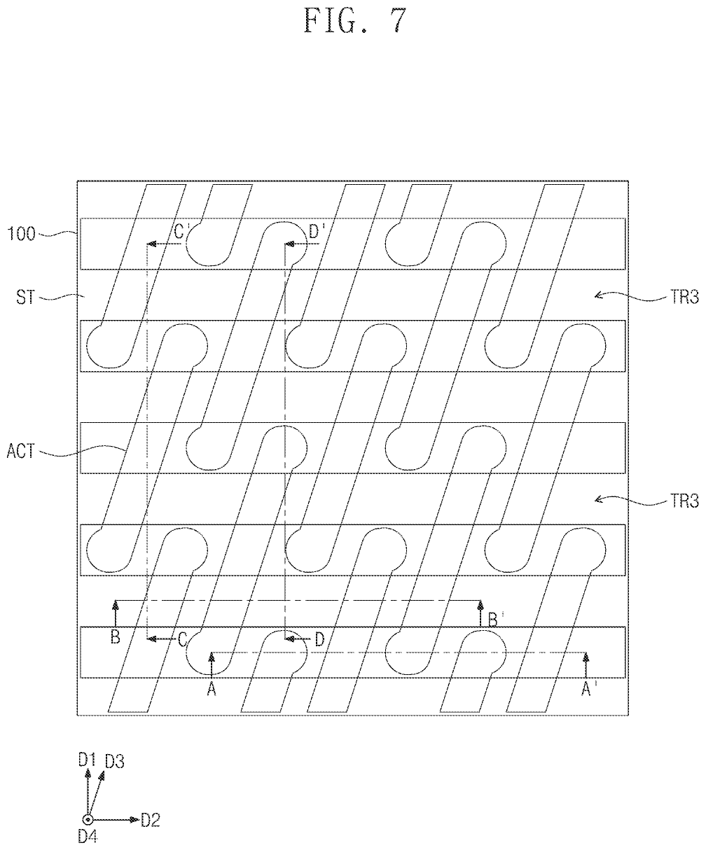

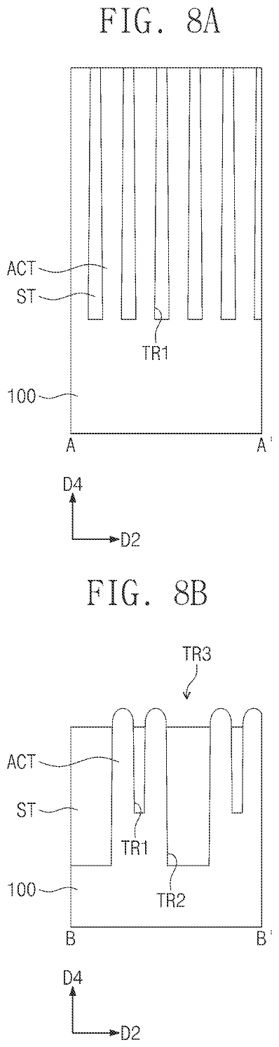

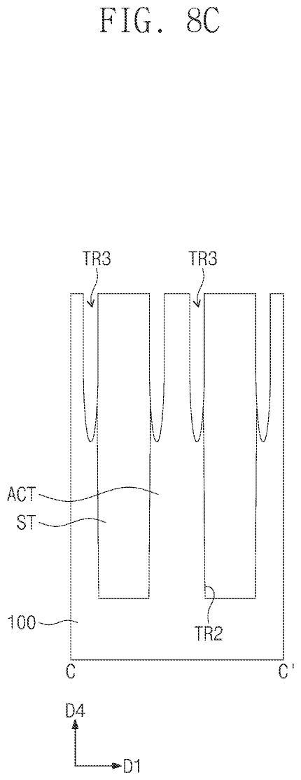

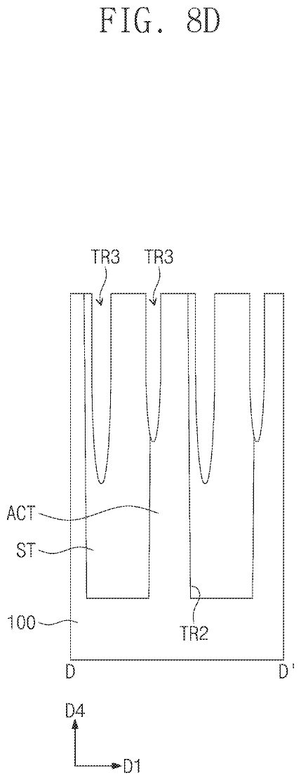

Referring to FIGS. 7 and 8A to 8D, the active patterns ACT and the device isolation layer ST may be patterned to form third trenches TR3. When viewed in plan, each of the third trenches TR3 may have a linear shape that extends in the second direction D2.

The formation of the third trenches TR3 may include forming a hardmask pattern having openings and then using the hardmask pattern as an etching mask to etch the active patterns ACT and the device isolation layer ST that are exposed. The third trench TR3 may be formed shallower than the first trench TR1.

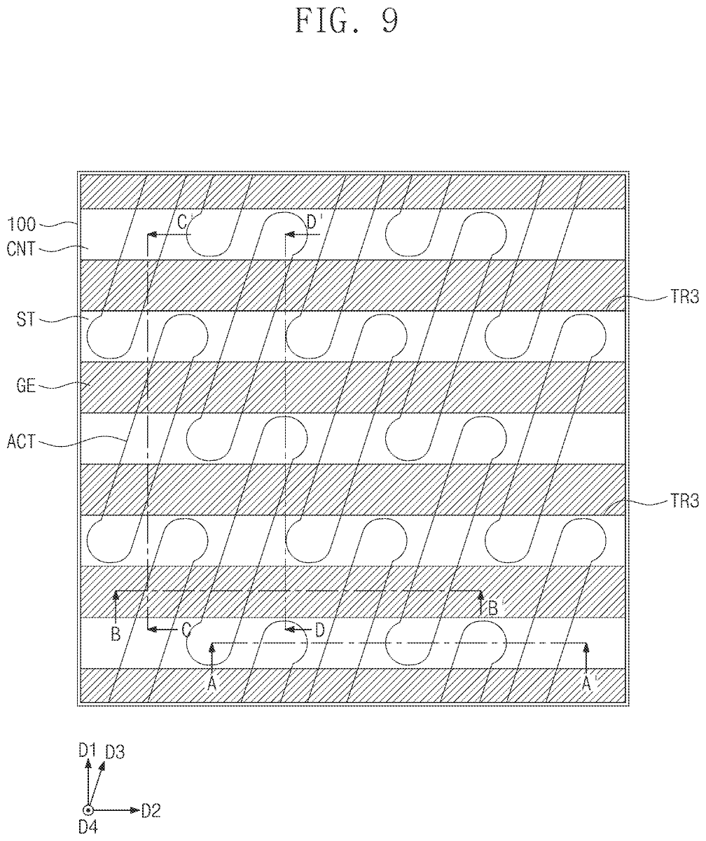

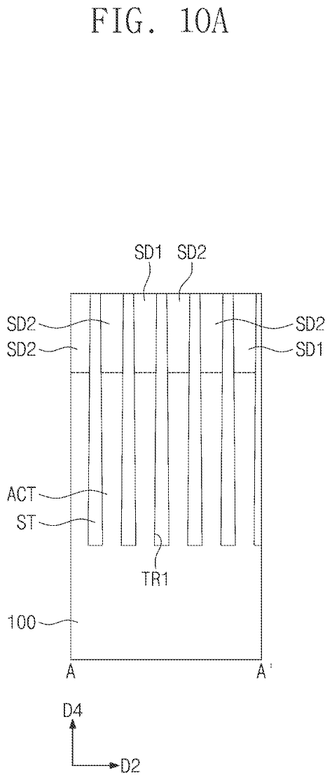

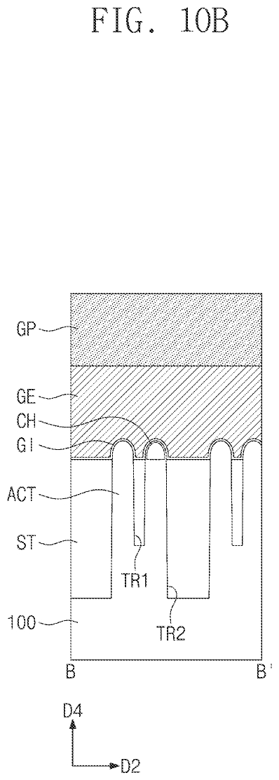

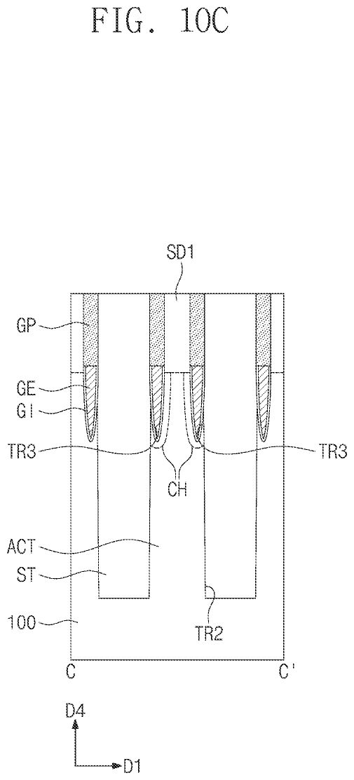

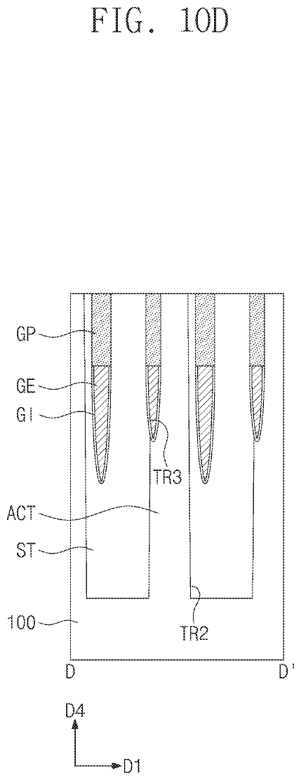

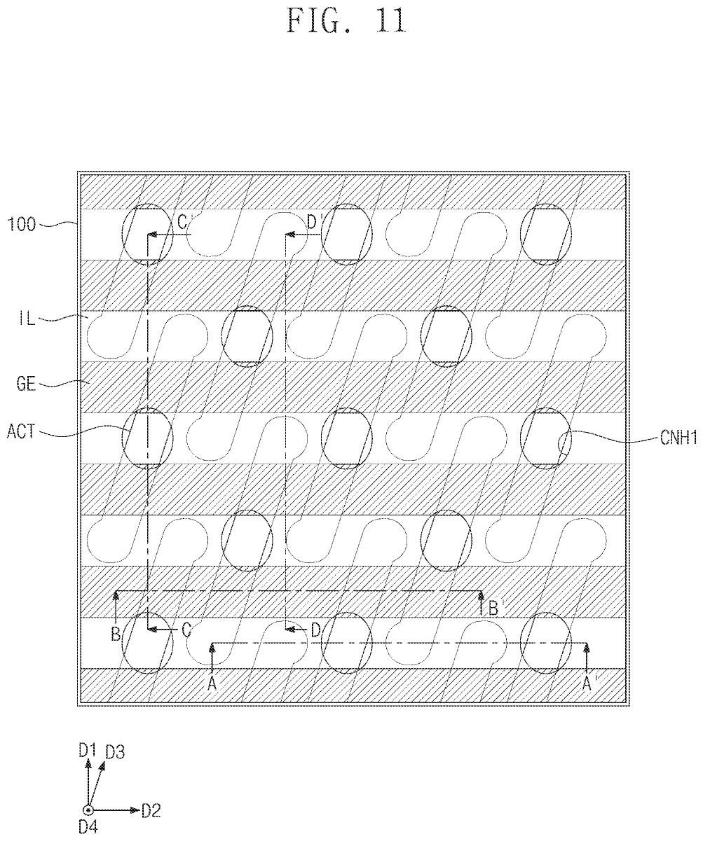

Referring to FIGS. 9 and 10A to 10D, a gate dielectric layer GI, a gate electrode GE, and a gate capping layer GP may be sequentially formed in each of the third trenches TR3. For example, the gate dielectric layer GI may be conformally formed in the third trench TR3. The gate dielectric layer GI may include one or more of a silicon oxide layer, a silicon nitride layer, a silicon oxynitride layer, and a high-k dielectric material.

The gate electrode GE may be formed by forming on the gate dielectric layer GI a conductive layer that fills the third trench TR3. The conductive layer may include one or more of metal and conductive metal nitride.

The gate dielectric layer GI and the gate electrode GE may be recessed, and then t

The active patterns ACT may undergo an ion implantation process to form a first source/drain region SD1 and a pair of second source/drain regions SD2 on an upper portion of the active pattern ACT. The pair of second source/drain regions SD2 may be spaced apart from each other in the third direction D3 across the first source/drain region SD1. For example, the first and second source/drain regions SD1 and SD2 may be doped with the same impurity.

A channel region CH may be defined on the active pattern ACT positioned below the gate electrode GE. When viewed in plan, the channel region CH may be interposed between the first source/drain region SD1 and the second source/drain region SD2. The gate electrode GE may be provided on a top surface and opposite sidewalls of the channel region CH (see FIG. 10C).

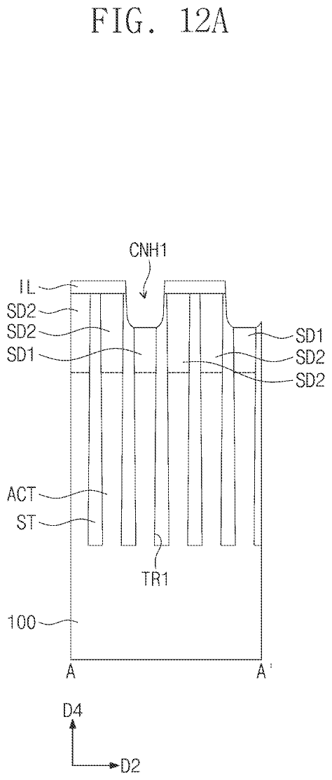

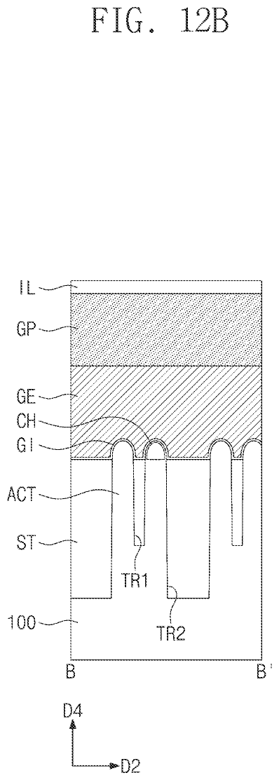

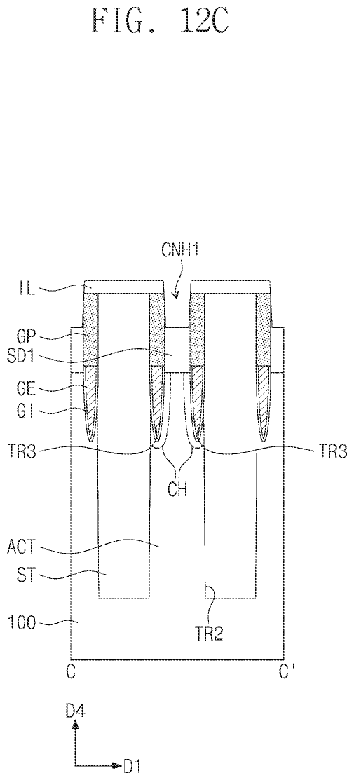

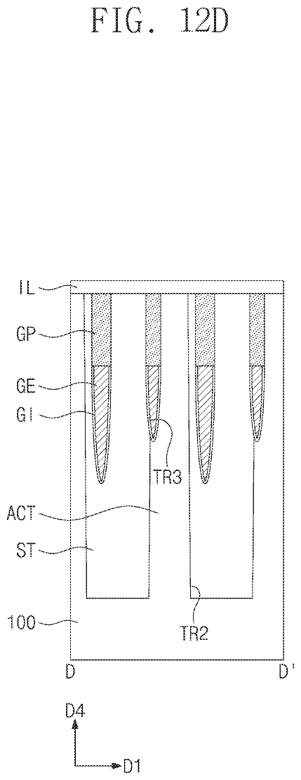

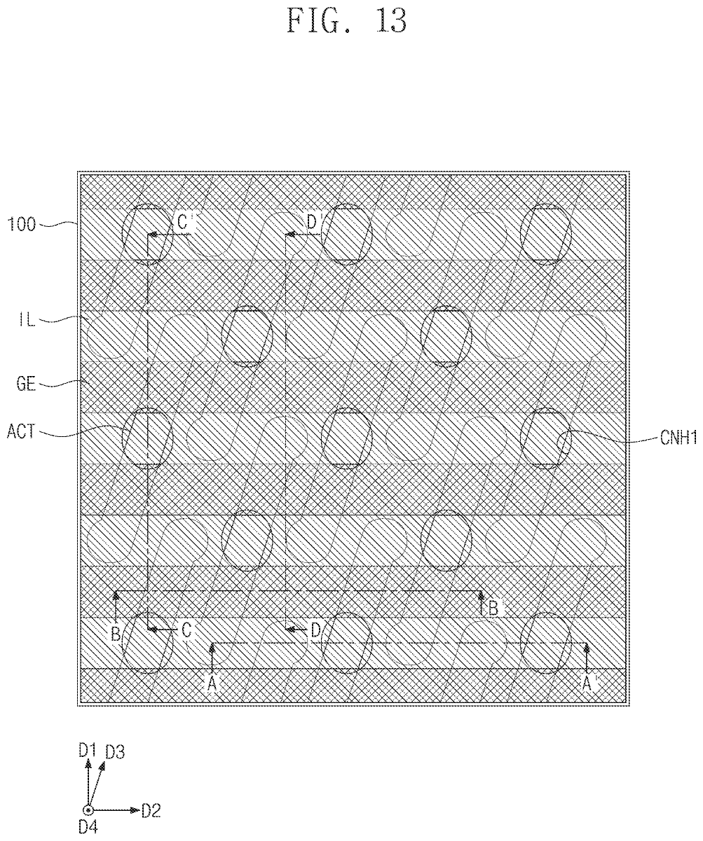

Referring to FIGS. 11 and 12A to 12D, a dielectric layer IL may be formed on an entire surface of the substrate 100. For example, the dielectric layer IL may have a multi-layered structure in which a silicon oxide layer and a silicon oxynitride layer are stacked. The dielectric layer IL may be patterned to form first contact holes CNH1 that correspondingly expose the first source/drain regions SD1 of the active patterns ACT. When the first contact hole CNH1 is formed, an upper portion of the first source/drain region SD1 may be recessed. The formation of the first contact hole CNH1 may recess an upper portion of the device isolation layer ST around the first source/drain region SD1.

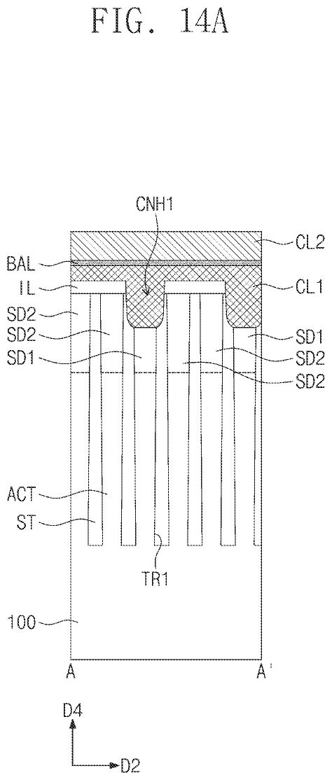

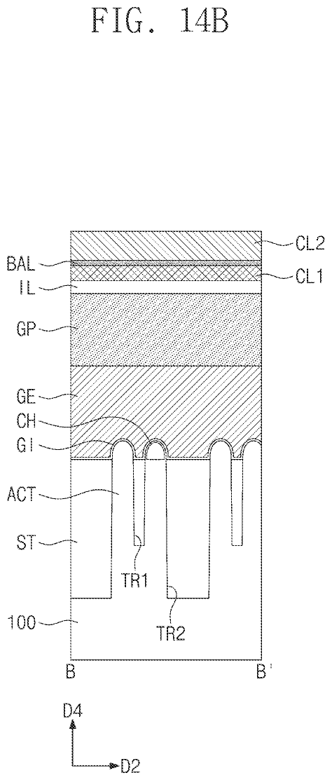

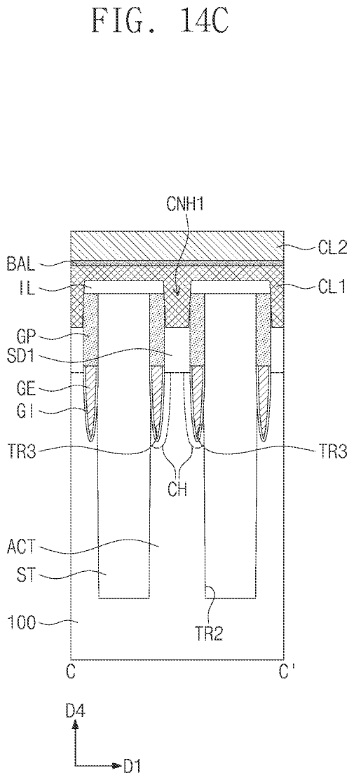

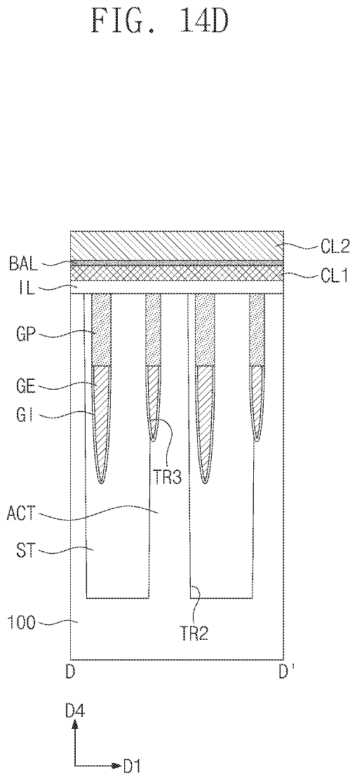

Referring to FIGS. 13 and 14A to 14D, a first conductive layer CL1, a barrier layer BAL, and a second conductive layer CL2 may be sequentially formed on the dielectric layer IL. The first conductive layer CL1 may fill the first contact holes CNH1. For example, the first conductive layer CL1 may be in contact with the first source/drain regions SD1 of the active patterns ACT. The dielectric layer IL may vertically separate the first conductive layer CL1 from the second source/drain regions SD2 of the active patterns ACT. The first conductive layer CL1 may include a doped semiconductor material.

The barrier layer BAL may be formed to lie between the first conductive layer CL1 and the second conductive layer CL2. The barrier layer BAL may include conductive metal nitride. The second conductive layer CL2 may include a metallic material. The barrier layer BAL may suppress the first conductive layer CL1 from receiving a metallic material diffused from the second conductive layer CL2.

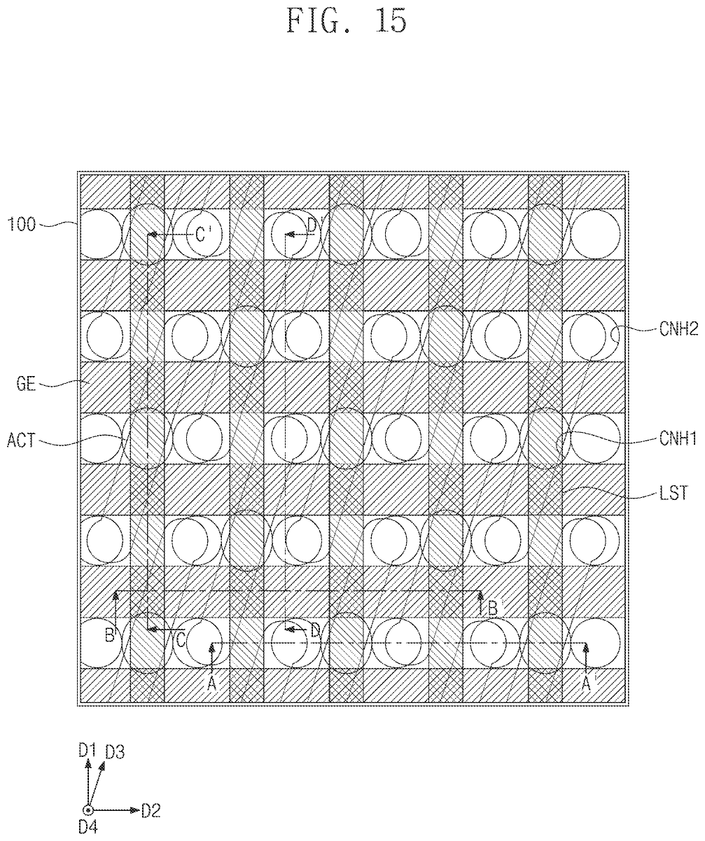

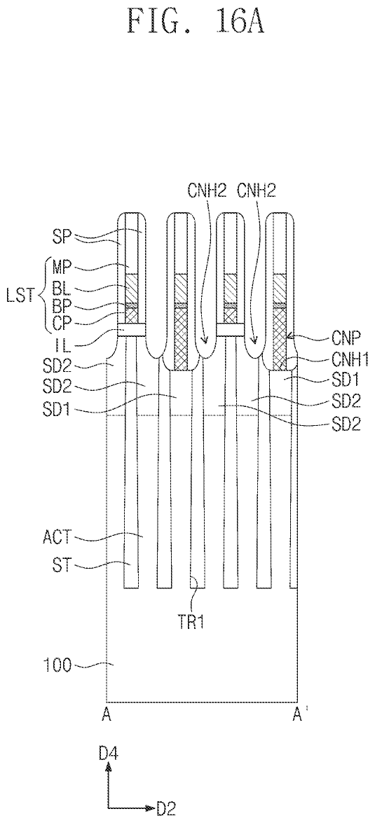

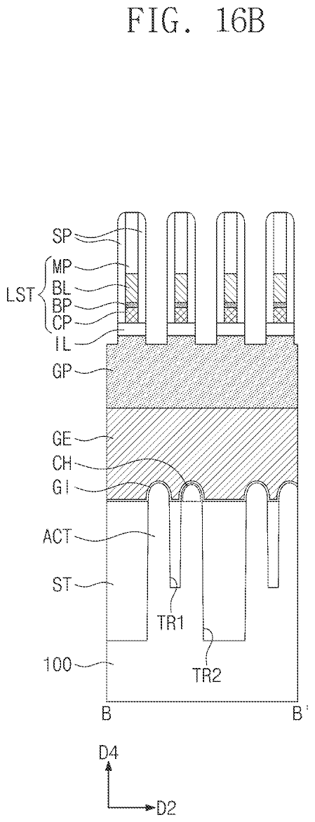

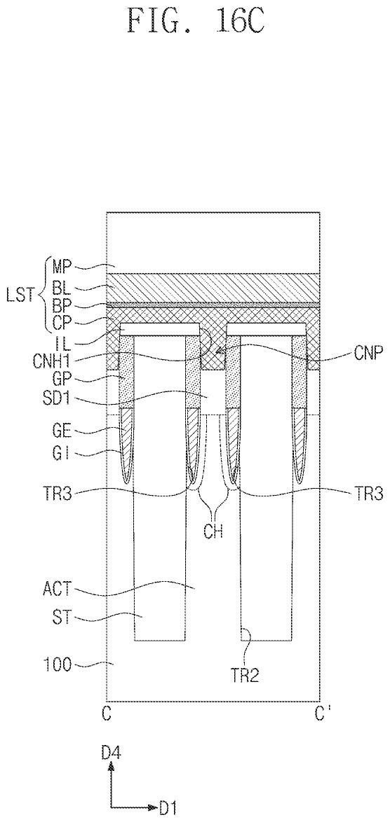

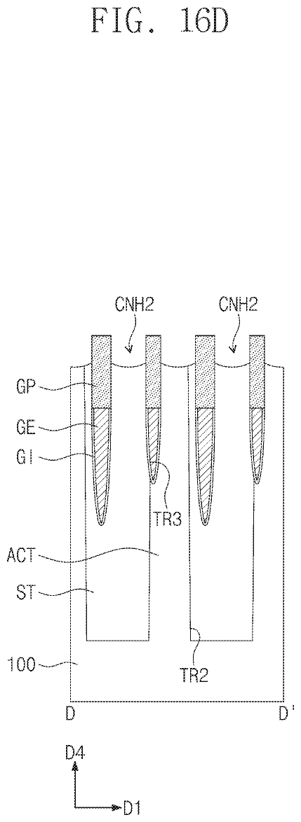

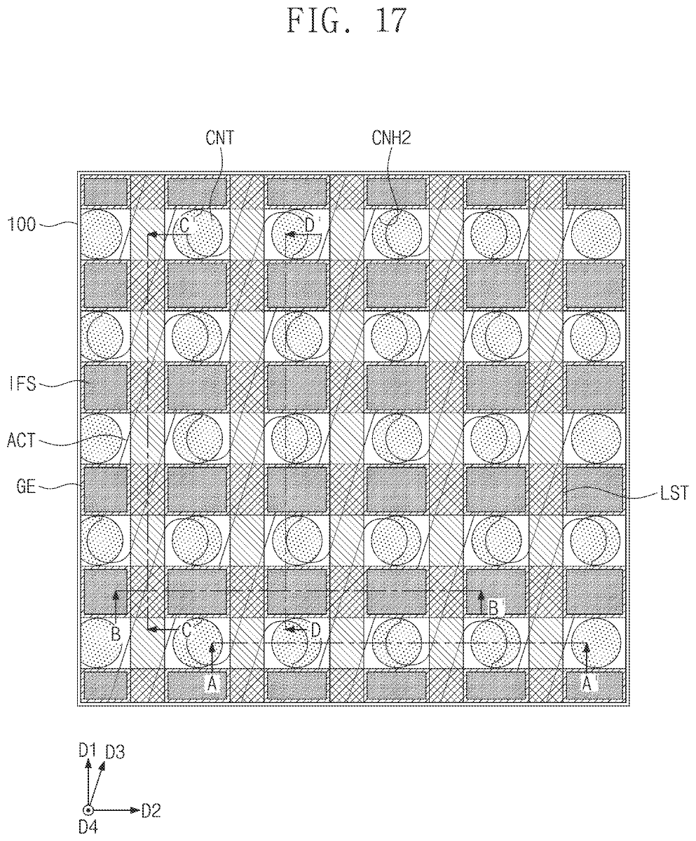

Referring to FIGS. 15 and 16A to 16D, line structures LST may be formed to extend in parallel to each other in the first direction D1 on the dielectric layer IL. The line structures LST may be arranged along the second direction D2, as illustrated in FIG. 15.

For example, mask patterns MP may be formed on the second conductive layer CL2. The mask patterns MP may be formed to have their linear shapes that extend in the first direction D1. For example, the mask patterns MP may include a silicon nitride layer or a silicon oxynitride layer.

The mask patterns MP may be used as an etching mask to sequentially etch the second conductive layer CL2, the barrier layer BAL, and the first conductive layer CL1 to form a bit line BL, a barrier pattern BP, and a conductive pattern CP, respectively. The mask pattern MP, the bit line BL, the barrier pattern BP, and the conductive pattern CP may vertically overlap each other. The mask pattern MP, the bit line BL, the barrier pattern BP, and the conductive pattern CP may constitute the line structure LST. When viewed in plan, the bit lines BL may extend while intersecting the gate electrodes GE.

The conductive pattern CP may include contact parts CNP that correspondingly fill the first contact holes CNH1. The conductive pattern CP may be connected through the contact part CNP to the first source/drain region SD1. For example, the bit line BL may be electrically connected through the conductive pattern CP to the first source/drain region SD1.

A pair of spacers SP may be formed on opposite sidewalls of each of the line structures LST. The formation of the spacers SP may include conformally forming a spacer layer on the entire surface of the substrate 100 and anisotropically etching the spacer layer.

The spacers SP and the mask patterns MP may be used as a mask to perform on the entire surface of the substrate 100 an etching process to form second contact holes CNH2 that correspondingly expose the second source/drain regions SD2. For example, the second contact hole CNH2 may penetrate the dielectric layer IL and downwardly extend from the top surface of the substrate 100. When the second contact hole CNH2 is formed, an upper portion of the second source/drain region SD2 may be recessed. The formation of the second contact hole CNH2 may recess an upper portion of the device isolation layer ST around the second source/drain region SD2. The spacers SP and the mask patterns MP may be used to form the second contact holes CNH2 in a self-aligned manner.

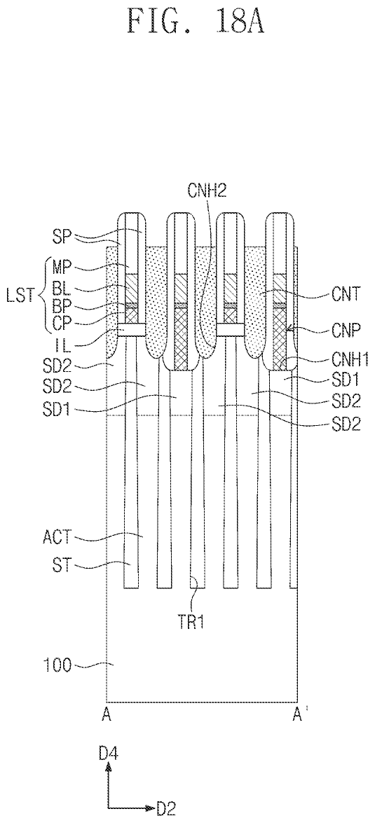

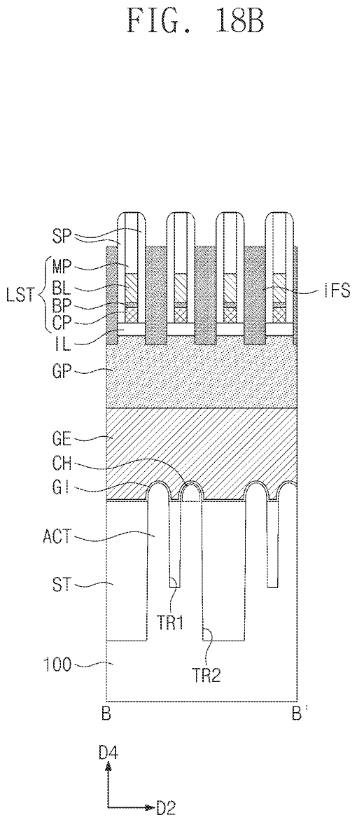

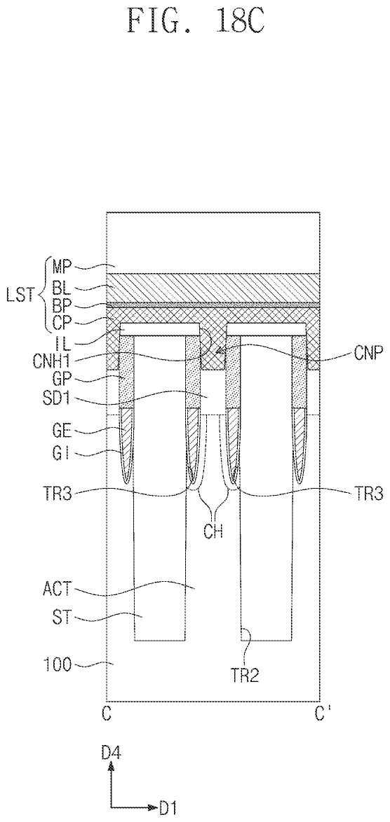

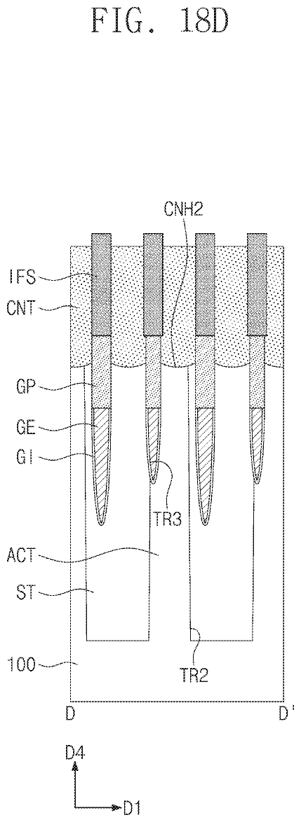

Referring to FIGS. 17 and 18A to 18D, a plurality of dielectric fences IFS may be formed on the gate capping layer GP. The dielectric fences IFS may not overlap, but expose the second contact holes CNH2.

The second contact holes CNH2 may be filled with a conductive material to form contacts CNT in the second contact holes CNH2. The contacts CNT may be connected to the second source/drain regions SD2. For example, the conductive material may be formed on the entire surface of the substrate 100, and then the conductive material may be recessed to have a top surface lower than those of the dielectric fences IFS. The dielectric fences IFS may divide the conductive material into pieces, and thus the contacts CNT may be correspondingly formed in the second contact holes CNH2. The contacts CNT and the dielectric fences IFS may be alternately arranged along the first direction D1.

The conductive material that fills the second contact holes CNH2 may be a doped semiconductor material. A doped semiconductor may fill the second contact holes CNH2, and then impurities may be allowed to diffuse from the doped semiconductor toward the second source/drain regions SD2. A metallurgical process may be used to diffuse the impurities.

Referring back to FIGS. 1, 2A, and 2C to 2E, landing pads LP may be formed on corresponding contacts CNT. For example, a metal layer may be formed on the contacts CNT and the dielectric fences IFS. The metal layer may be patterned to form a plurality of landing pads LP. A gap between the plurality of landing pads LP may be filled with a dielectric material to form a dielectric pattern INP. First electrodes LEL may be formed on corresponding landing pads LP. A dielectric layer HDL may be conformally formed on the first electrodes LEL. A second electrode TEL may be formed on the dielectric layer HDL. The first electrode LEL, the dielectric layer HDL, and the second electrode TEL may constitute a data storage element DS, for example, a capacitor. Although not shown, stacked wiring layers (e.g., M1, M2, M3, M4, and the like) may be formed on the second electrode TEL.

According to some embodiments of the inventive concepts, each of active contacts may have a width at its upper portion greater than a width at its lower portion. Therefore, each of the active contacts in contact with contacts may have an increased area, and as a result, a semiconductor memory device may be provided which has improved contact properties and increased electrical characteristics.

Although the present inventive concepts have been described in connection with some embodiments of the present inventive concepts illustrated in the accompanying drawings, it will be understood by one of ordinary skill in the art that variations in form and detail may be made therein without departing from the scope of the present inventive concepts. The above disclosed embodiments should be considered illustrative and not restrictive.

What is claimed is:

1. A semiconductor memory device, comprising:
a substrate comprising a plurality of active patterns, each of the plurality of active patterns comprising a first source/drain region and second source/drain regions;
a gate electrode extending across the plurality of active patterns in a first direction between the first and second source/drain regions;
a line structure extending across the plurality of active patterns in a second direction which is transverse to the first direction, the line structure comprising a bit line electrically connected to the first source/drain region;
a device isolation layer within a first trench which defines the plurality of active patterns; and
a plurality of contacts coupled to the second source/drain regions,
wherein, when viewed in plan, each of the plurality of active patterns comprises:
a first portion extending in a third direction parallel to a top surface of the substrate; and
a second portion and a third portion respectively connected to opposite ends of the first portion, wherein the second and third portions vertically overlap respective ones of the plurality of contacts, and
wherein the second portion and the third portion extend from the first portion toward the respective ones of the plurality of contacts.

2. The semiconductor memory device of claim 1, wherein a width of the first portion is less than a width of the second portion and a width of the third portion.

3. The semiconductor memory device of claim 2, wherein a ratio of the width of the second portion to the width of the first portion is in a range of about 1.05 to about 1.2, and wherein a ratio of the width of the third portion to the width of the first portion is in a range of about 1.05 to about 1.2.

4. The semiconductor memory device of claim 1, wherein, when viewed in plan, the second portion and the third portion protrude from the first portion toward the respective ones of the plurality of contacts in a direction parallel to the first direction.

5. The semiconductor memory device of claim 4, wherein a protruding direction of the second portion is opposite to a protruding direction of the third portion.

6. The semiconductor memory device of claim 4, wherein, when viewed in plan, the second portion and the third portion are symmetrical.

7. The semiconductor memory device of claim 1, wherein a width of the second portion increases with decreasing distance from one of the plurality of contacts that is closest to the second portion.

8. The semiconductor memory device of claim 1, wherein a width of the second portion and a width of the third portion each decrease with decreasing distance from a bottom surface of the substrate.

9. The semiconductor memory device of claim 1, wherein the plurality of active patterns comprise a first active pattern and a second active pattern that are spaced apart from each other across the device isolation layer,
wherein a width of the device isolation layer between the second active pattern and the second portion of the first active pattern increases with decreasing distance from a bottom surface of the substrate.

10. A semiconductor memory device, comprising:
a substrate comprising a plurality of active patterns, each of the plurality of active patterns comprising a first source/drain region and a second source/drain region;
a gate electrode extending across the plurality of active patterns in a first direction between the first and second source/drain regions;
a line structure extending across the plurality of active patterns in a second direction which is transverse to the first direction, the line structure comprising a bit line electrically connected to the first source/drain region;
a device isolation layer within a first trench which defines the plurality of active patterns; and
a contact coupled to the second source/drain region,
wherein a width of each of the plurality of active patterns increases with increasing distance from a bottom surface of the substrate.

11. The semiconductor memory device of claim 10, wherein a width of the device isolation layer decreases with increasing distance from the bottom surface of the substrate.

12. The semiconductor memory device of claim 10, wherein a ratio of a width of the device isolation layer at a lowermost surface to a width of the device isolation layer at an uppermost surface is in a range of about 1.05 to about 1.2.

13. The semiconductor memory device of claim 10, wherein the plurality of active patterns include a first active pattern and a second active pattern that are spaced apart from each other across the device isolation layer,
wherein an interval between the first active pattern and the second active pattern decreases with decreasing distance from a top surface of the substrate.

14. The semiconductor memory device of claim 13, wherein a minimum width of the device isolation layer between the first active pattern and the second active pattern is in a range of about 50 nm to about 100 nm.

15. The semiconductor memory device of claim 10, wherein a maximum width of each of the plurality of active patterns is in a range of about 60 nm to about 100 nm.

16. The semiconductor memory device of claim 10, further comprising:
a landing pad on the contact; and
a data storage element on the landing pad.

17. The semiconductor memory device of claim 16, wherein the data storage element comprises:
a first electrode on the landing pad;
a second electrode on the first electrode; and
a dielectric layer between the first electrode and the second electrode.

18. A semiconductor memory device, comprising:
a substrate comprising a plurality of active patterns, each of the plurality of active patterns comprising a first source/drain region and a second source/drain region;
a gate electrode extending across the plurality of active patterns in a first direction between the first and second source/drain regions;
a dielectric layer on the substrate;
a line structure extending across the plurality of active patterns in a second direction on the dielectric layer, wherein the second direction is transverse to the first direction, wherein the line structure comprises a conductive pattern coupled to the first source/drain region, a bit line on the conductive pattern, and a barrier pattern between the bit line and the conductive pattern;
a pair of spacers on opposite sidewalls of the line structure;
a device isolation layer within a first trench which defines the plurality of active patterns;
a plurality of contacts coupled to the second source/drain region, wherein the plurality of contacts are in contact with corresponding spacers that separate the plurality of contacts from the line structure;
a landing pad on each of the plurality of contacts; and
a data storage element on each landing pad,
wherein each data storage element comprises:
a first electrode on a respective landing pad;
a second electrode on the first electrode; and
a dielectric layer between the first electrode and the second electrode, and
wherein, when viewed in plan, each of the plurality of active patterns comprises:
a first portion extending in a third direction parallel to a top surface of the substrate; and
a second portion and a third portion respectively connected to opposite ends of the first portion, wherein the second and third portions vertically overlap respective ones of the plurality of contacts,
wherein the second portion and the third portion extend from the first portion toward the respective ones of the plurality of contacts.

19. The semiconductor memory device of claim 18, wherein, when viewed in plan, the second portion and the third portion protrude from the first portion toward the respective ones of the plurality of contacts in a direction parallel to the first direction.

20. The semiconductor memory device of claim 18, wherein a width of the second portion and a width of the third portion increase with decreasing distance from the respective ones of the plurality of contacts.
